(19) United States
(12) Patent Application Publication
(10) Pub. No.: US 2007/0123055 A1
(43) Pub. Date: May 31, 2007

(54) Insulating material

(75) Inventors: Tomonori Ishikawa, Hekinan-city (JP); Akio Sugiura, Kariya-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/605,512

(22) Filed: Nov. 28, 2006

(30) Foreign Application Priority Data
Nov. 30, 2005 (JP) 2005-345554

(51) Int. Cl. H01L 23/58; H01L 21/31

(52) U.S. Cl. 438/758; 257/629

(57) ABSTRACT

Disclosed is an insulating material containing an epoxy resin, a curing agent and a nano-filling material having an aspect ratio of not more than 40 at a thickness of not more than 2 nm. The nano-filling material comprises an organized clay dispersed in the epoxy resin. The organized clay is produced from a clay mineral having a layered structure by organically treating the clay mineral with organic secondary, tertiary or quaternary ammonium ions having a nitrogen atom bonded with two, three or four organic modifying groups. The organic modifying group preferably has not more than 30 carbon atoms. At least one modifying group among the organic modifying groups has two or more carbon atoms. The insulating material can exhibit an excellent insulating property without causing substantial loss of the characteristics inherent to the resin.

### BACKGROUND OF THE INVENTION

1. Field of the Invention

The present invention relates to an electrically insulating material comprising an epoxy resin having dispersed therein a filling material or a filler.

2. Description of the Related Art

Heretofore, it was known that an insulating material could include an injection molding material comprising, for example, an epoxy resin having dispersed therein a filling material consisting of silica. As it has the epoxy resin as a resin component, the injection molding material can exhibit the characteristics of the epoxy resin, thereby enabling it to provide an excellent heat resistant property, in addition to an insulating property. Therefore, the injection molding material has been used in applications including, for example, an ignition coil of an automobile and others (see, Japanese Unexamined Patent Publication (Kokai) No. 11-111547). In this injection molding material, the insulating property thereof can be improved with increase of an amount of the filling material added.

On the other hand, recently, attention has been given to a composite material comprising a resin material having dispersed therein an organized clay obtained by subjecting a clay to an organic treatment. More particularly, there has been developed a composite resin material comprising an organized clay dispersed in the epoxy resin (see, The Journal of Adhesion Society of Japan, the Adhesion Society of Japan, No. 11, Vol. 40, 2004, p. 532-535). In this composite resin material, the dispersion of the organized clay is effective to improve the mechanical properties of the resulting composite resin material, in comparison with that of the epoxy resin itself.

However, there is a problem, in the above-described injection molding material, that, when the amount of the filling material added is increased to improve the heat resistance property, the characteristics originated from the epoxy resin can be deteriorated, thereby causing a loss of the heat resistance property and others. Further, an application of the electric power for a long time of period tends to cause a dielectric breakdown problem. Moreover, in the above-described resin material having dispersed therein the organized clay, there is no description concerning the insulating property, although it can improve the mechanical properties such as tensile strength and the like.

### SUMMARY OF THE INVENTION

The object of the present invention is to provide an insulating material capable of exhibiting an excellent electrically insulating property without causing substantial loss of the characteristics of the resin itself.

The present invention resides in an insulating material comprising an epoxy resin, a curing agent and a nano-filling material i.e., filling material having a size of an order of nanometer, having an aspect ratio of not more than 40 at a thickness of not more than 2 nm, characterized in that

the nano-filling material or nano-sized filling material comprises a organized clay dispersed in the epoxy resin, and

the organized clay comprises a clay mineral having a layered structure organically treated with organic secondary, tertiary or quaternary ammonium ions having a nitrogen atom bonded with two, three or four organic modifying groups.

The insulating material according to the present invention comprises the nano-filling material comprising an organized clay dispersed in an epoxy resin, the organized clay being produced by organizing or organically treating a clay mineral with specific organic ammonium ions, an epoxy resin and a curing agent. In the insulating material, when the organized clay is dispersed in the epoxy resin, a layered structure of the organized clay is destroyed and thus a nano-filling material, for example, in the form of plates having an aspect ratio of not more than 40 at a thickness of not more than 2 nm is dispersed in the epoxy resin.

Therefore, the present insulating material can provide an excellent insulating property. Further, in comparison with the prior art filling materials consisting of silica, the present insulating material can provide a satisfactory insulating property even if it contains only a small amount of the nano-filling material. As a result, the insulating material can exhibit an excellent heat resistance property without deteriorating the characteristics, such as heat resistance and others, which are inherent to the epoxy resin.

Moreover, the present insulating material can still exhibit an excellent insulating property after curing of the insulating material.

Hereinafter, the reason why the excellent insulating property, describe above, can be exhibited in the insulating material of the present invention will be described with reference to FIGS. 1 and 5.

FIG. 1 illustrates a prior art insulating material 9 prepared by adding a filling material 95 consisting of silica to an epoxy resin 90. As illustrated in this drawing, the insulating material 9 is a molded product in the form of a rectangle. One surface of the rectangular insulating material 9 has an electrically conductive surface 98 produced by baking a conductive paste, and dielectric breakdown is caused in the insulating material 9 when an electrode needle 9 is inserted from a surface opposed to the conductive surface 98 into the insulating material 9 to continuously apply a voltage above a predetermined level. FIG. 1 illustrates the progress of the dielectric breakdown (shown with the heavy arrow line in FIG. 1), when the dielectric breakdown is caused in the prior art insulating material 9.

As illustrated in FIG. 1, generally, the dielectric breakdown progresses with detours in the insulating material 9 by avoiding the filling material 95 in the epoxy resin 90. Thus, as shown in the same drawing, in the case of adding a filling material 95 to the epoxy resin 90, the progress length (length of the heavy arrow line in FIG. 1) of the dielectric breakdown extends the length of the detour route, thereby making dielectric breakdown difficult. As can be appreciated from this drawing, as the prior art filling material consisting of silica and others has a large volume, it is difficult to increase a length of the detour route with addition of a small amount of such a prior art filling material.

Contrary to this, as illustrated in FIG. 5, in the insulating material 1 of the present invention, an epoxy resin 2 contains a very small nano-filling material 3, dispersed in the epoxy resin 2, having an aspect ratio of 40 or less at a thickness of 2 nm or less. Therefore, the length of the progress route (heavy arrow line in FIG. 5) can be easily increased with the addition of a relatively small amount of filling material 1. As a result, it is considered that dielectric breakdown can occur only with difficulty, thereby providing a highly increased insulating property. Note, in FIG. 5, that it illustrates progress of the dielectric breakdown which is caused in the rectangular insulating material 1 having the formed conductive surface 10 when an electrode needle 8 is inserted into the insulating material 1 to apply an electrical voltage to the insulating material 1.

As described above, the insulating material of the present invention dielectric breakdown occurs with difficulty even with a small content of the nano-filling material, thereby providing an excellent insulating property.

Accordingly, according to the present invention, it becomes possible to provide an insulating material having an excellent insulating property without a substantial loss of the characteristics inherent to the resin.

### BRIEF DESCRIPTION OF THE DRAWINGS

FIG. 1 is an illustration showing the progress of the dielectric breakdown in the prior art insulating material;

FIG. 2 is an illustration showing the constitution of the insulating material according to Example 1;

FIG. 3A is an illustration showing a layered structure of the clay mineral according to Example 1;

FIG. 3B is an illustration showing a constitution of the organized clay wherein organic ammonium ions were inserted between the layers of the clay mineral;

FIG. 4 is an illustration showing the measuring method of the withstand voltage in Example 1; and

FIG. 5 is an illustration showing the progress of the dielectric breakdown in the insulating material of the present invention.

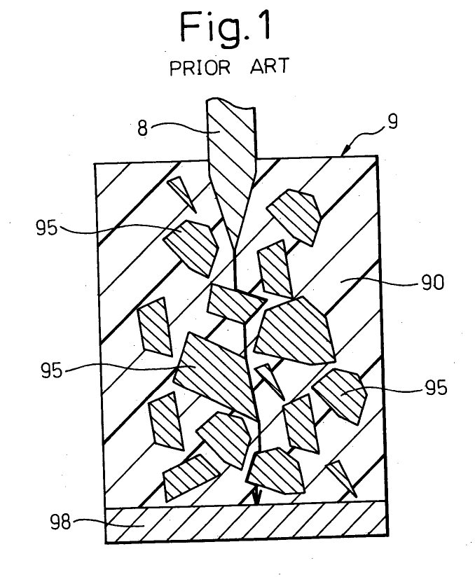

### DESCRIPTION OF THE PREFERRED EMBODIMENTS

The present invention will be described with regard to the preferred embodiments thereof. It should be noted, however, that the present invention is not restricted to the described embodiments, and thus the embodiments may be modified or improved within the scope and spirit of the invention.

The insulating material of the present invention contains an epoxy resin, a curing or hardening agent and a nano-filling material or nano-filler having an aspect ratio of 40 or less at the thickness of 2 nm or less.

When the thickness of the nano-filling material is above 2 nm, or when the aspect ratio thereof is above 40, a specific surface area of the nano-filling material dispersed in the insulating material is reduced. As a result, in such cases, the progress length of the dielectric breakdown in the insulating material is easily shortened and an insulating property of the insulating material tends to be reduced. In addition, when the aspect ration is above 40, the excellent mechanical characteristics of the epoxy resin tend to be deteriorated.

An aspect ratio of the nano-filling material can be represented by a ratio of the width (the longest length) of the nano-filling material to the thickness (the shortest length) thereof.

The thickness and width of the nano-filling material can be varied by suitably selecting the clay mineral. Accordingly, the thickness and width of the nano-filling material can be roughly determined as a result of selection of the type of the clay mineral.

Further, the thickness and width of the nano-filling material in the insulating material can be obtained by measuring the cured insulating material with, for example, an X-ray diffraction method, a transmission electron microscope (TEM) and others.

Moreover, the organized clay is a product of the clay mineral organized with the organic ammonium ions.

The organization or organic treatment can be carried out, for example, by immersing the clay mineral in a liquid such as an aqueous solution containing the organic ammonium ions or other methods. As a result of the organization treatment, the organic ammonium ions introduced between the layers constituting the clay mineral, thereby widening a space or gap between the layers. Accordingly, using the organization treatment, the above-described organized clay having an expanded space between the layers as a function of insertion of the organic ammonium ions between the layers of the clay mineral can be obtained.

Further, in the nano-filling material, the organized clay is dispersed in the epoxy resin.

When the organized clay is dispersed in the epoxy resin by, for example, mixing and others, the epoxy resin is intruded between the layers of the organized clay, thereby breaking the bond between the layers, and thus the layers constituting the organized clay are dispersed as the nano-filling material in the epoxy resin.

In this dispersion process, the layers constituting the organized clay may be dispersed as a single layer in the epoxy resin, or they may be dispersed as a laminated product of two or more layers. Preferably, the layers are dispersed as a single layer. In such a case, a thickness of the nano-filling material may be reduced to a order of about 1 nm. Moreover, in such a case, the dielectric breakdown of the resulting insulating material can be more effectively inhibited, because a sum of the specific surface area of the nano-filling material in the insulating material can be increased with addition of a small amount (weight) of the organized clay.

Furthermore, the insulating material contains a curing agent.

The curing agent includes, for example, an acid anhydride, an amine compounds and others.

The acid anhydride includes, for example, hexahydroic acid anhydride, phthalic acid anhydride, maleic acid anhydride, methylcyclodextrinic (methyl CD) acid anhydride, cyclodextrinic (CD) acid anhydride, metylhimic acid anhydride, himic acid anhydride, succinic acid anhydride, tetrahydoroic acid anhydride, rikazide HL, chlorendic acid anhydride, methyltetrahydrophthalic acid anhydride, trialkyltetrahydrophthalic acid anhydride, 3-methylhexahydrophthalic acid anhydride, 4-methylhexahydrophthalic acid anhydride, trialkyltetrahydrophthalic acid anhydride maleic acid adduct, metylhexahydrophthalic acid anhydride, benzophenonetetracarboxylic acid anhydride, dodecenylsuccinic acid anhydride, trimellitic acid anhydride, pyromellitic acid anhydride, methylnagic acid anhydride and other anhydrides.

Further, it is preferred that the content of the curing agent is in the range of 30 to 170 parts by weight per 100 parts by weight of the epoxy resin.

In this case, the insulating material can be hardened without deteriorating the characteristics inherent to the epoxy resin.

In addition, the organized clay is obtained from the clay mineral having the layered structure by organizing or organically treating it with organic secondary, tertiary or quaternary ammonium ions which have two to four organic modifying groups attached to the nitrogen atom thereof.

When the organic treatment of the layer mineral is carried out by using, as an organic ammonium, a primary ammonium compound having one organic modifying group attached to a nitrogen atom thereof, the primary ammonium compound can adversely effect the curing reaction of the epoxy resin during curing of the insulating material upon heating thereof, thereby lowering the insulating property of the resulting cured product.

The structures of the secondary, tertiary and quaternary ammonium ions are represented by the following formulae (1) to (3) in which R₁ to R₃ each represents an organic modifying group.

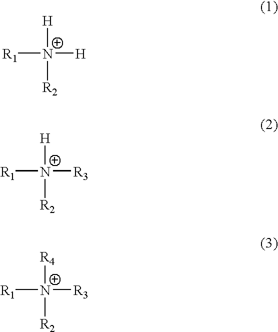

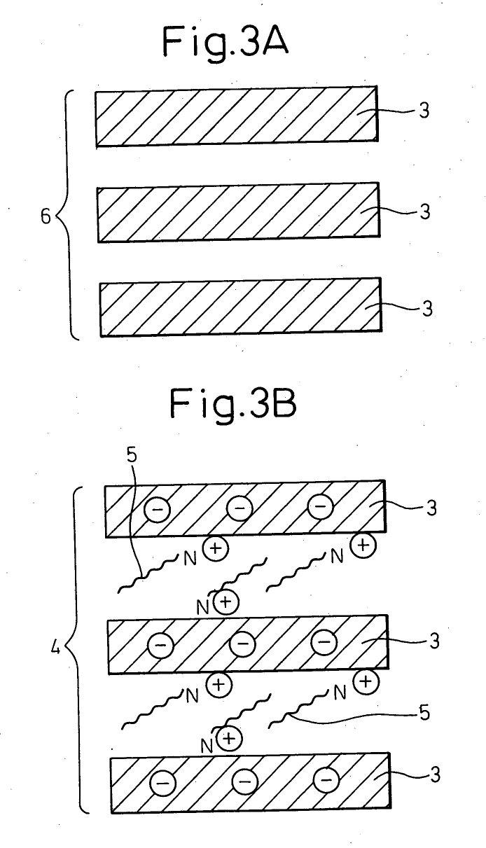

As shown in the formulae (1) to (3), in the organic ammonium ions, a nitrogen (N) atom to which the organic modifying group is attached has a positive charge. Accordingly, upon contact of the clay mineral with the organic ammonium ions, the organic ammonium ions intrude between, and are bonded to a surface of, the layers of the clay mineral by the function of, for example, the positive charge of the N atom of the ammonium ions, thereby increasing the distance between the layers of the clay mineral (organization treatment; see, FIGS. 3A and 3B).

The clay mineral having the inserted organic ammonium ions, that is, the organized clay described above, thus exhibits an enlarged distance between the layers constituting the same. Accordingly, when the organic clay is mixed with and dispersed in the epoxy resin, the epoxy resin can easily intrude between the layers of the organized clay. As a result, the distance between layers of the organized clay is increased to cause a breakage of the bond of the layers of the organized clay, thus enabling the layers constituting the organized clay to disperse, as a nano-filling material, in the epoxy resin.

In the organic ammonium ions described above, the organic modifying group includes hydrocarbon groups such as alkyl groups, cycloalkyl groups, alkenyl groups and others. Further, the organic modifying group may be one containing functional groups having a relatively large polarity and a high reactivity such as hydroxyl groups, carboxyl groups and the like.

Preferably, the organic modifying group of the organic ammonium ions has not more than 30 carbon atoms.

When the number of the carbon atoms is above 30, there is a tendency that the organic ammonium ions hardly intrude between the layers of the clay mineral. Accordingly, it becomes difficult to sufficiently widen the distance between the layers of the organized clay, and thus there arises a tendency that the resulting nano-filling material is sufficiently dispersed only with difficulty in the epoxy resin.

Further, with regard to the organic modifying groups in the organic ammonium ions, it is preferred that at least one organic modifying group has two or more carbon atoms.

When the organic modifying groups in the organic ammonium ions each has less than two carbon atoms, it becomes difficult to sufficiently widen the distance between the layers of the organized clay and, as a result, there arises a tendency that the resulting nano-filling material is sufficiently dispersed only with difficulty in the epoxy resin. At least one of the organic modifying groups in the organic ammonium ions preferably has 10 or more carbon atoms, more preferably 15 or more carbon atoms.

It is preferred that at least one of the organic modifying groups in the organic ammonium ions has two or more carbon atoms, and the reminder of the organic modifying groups has 30 or less carbon atoms.

In this case, the organic ammonium ions can easily intrude between the layers of the clay mineral and, at the same time, the distance of the layers of the clay mineral can be sufficiently widened.

Further, at least one member selected from montmorillonite, sabonite, beidellite, nontronite, hectorite and stevensite can be used as the clay mineral.

Furthermore, it is preferred that the insulating mineral contains 1 to 35 parts by weight (pbw) of the nano-filling material per 100 parts by weight of the epoxy resin.

When the blending ratio of the nano-filling material is within the above-described range, it becomes possible to obtain the functions and effects of the present invention and an excellent insulating property can be provided with use of a small amount of the nano-filling material. More preferably, the content of the nano-filling material in the insulating material is in the range of 1 to 20 parts by weight, and most preferably in the range of 1 to 10 parts by weight.

Moreover, at least one member selected from, for example, bisphenol A-type epoxy resin, bisphenol F-type epoxy resin, bisphenol S-type epoxy resin, hexahydrobisphenol A-type epoxy resin, tetramethylbisphenol A-type epoxy resin, pyrocatechol-type epoxy resin, resorcinol-type epoxy resin, cresol/novolak-type epoxy resin, tetrabromobisphenol A-type epoxy resin, trihydroxybiphenyl-type epoxy resin, bisresorcinol-type epoxy resin, tetramethylbisphenol F-type epoxy resin, bixylenol-type epoxy resin and others can be used as the epoxy resin.

### EXAMPLES

The present invention will be further described with regard to the examples thereof.

### Example 1

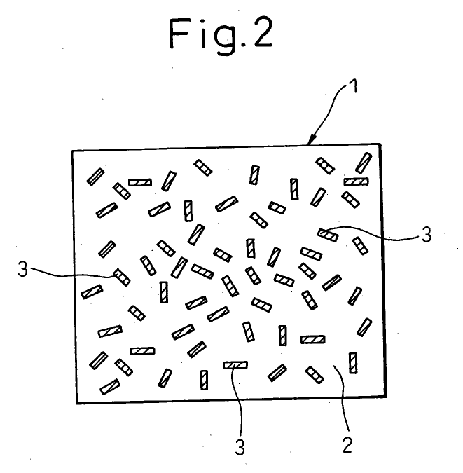

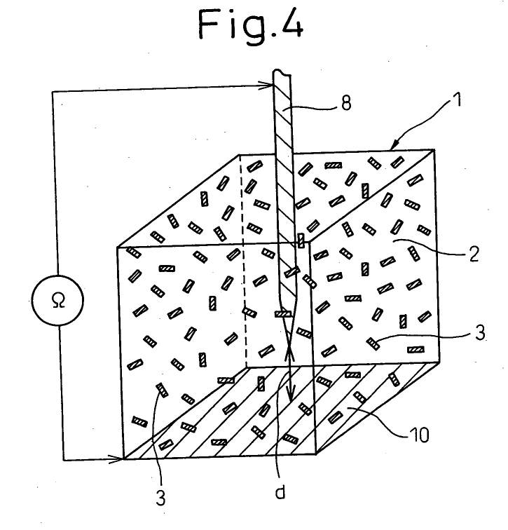

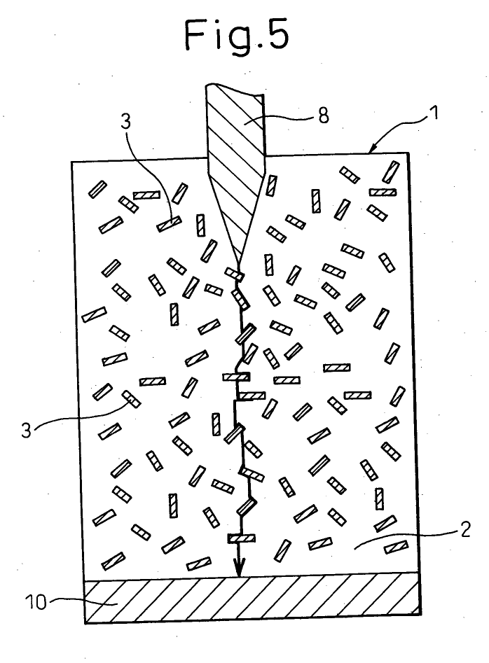

This example will be explained with reference to FIG. 2, FIGS. 3A and 3B and FIG. 4. Note, in this example, that the insulating material as the example of the present invention and the comparative insulating material are prepared to compare the insulating property of these two insulating materials.

As shown in FIG. 2, the insulating material 1 of this example contains an epoxy resin 2, a curing agent, and a plate-shaped nano-filling material 3 having a thickness of not more than 2 nm and an aspect ratio of not more than 40. The nano-filling material 3 comprises the organized clay dispersed in the epoxy resin 2. As shown in FIGS. 3A and 3B, the organized clay 4 is produced by an organization treatment of the clay mineral 6 having the layered structure with organic secondary, tertiary or quaternary ammonium ions 5 having 2 to 4 organic modifying groups attached to a nitrogen atom thereof.

In this example, montmorillonite was used as the clay mineral 6. Further, the compound, represented by the following formula (4), having as the organic modifying group an alkyl group of 18 carbon atoms and a methyl group of one (1) carbon atom (N-methyl n-octadecylammonium ion) was used as the organic ammonium ion 5.

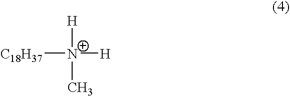

Hereinafter, the production process of the insulating material used in this example will be described.

First, the clay mineral having the layered structure was subjected to the organization treatment to prepare a organized clay.

More particularly, montmorillonite having the layered structure (Na-montmorillonite) was provided as the clay mineral 6 (see, FIG. 3A). The clay mineral was dispersed in water to prepare a dispersion thereof.

Next, an organic ammonium salt was provided, and the ammonium salt was dissolved in water to prepare an aqueous solution of the organic ammonium. The resulting aqueous solution contains an organic ammonium ion of the above formula (4).

Thereafter, the aqueous solution of the organic ammonium was added to a dispersion of the clay mineral prepared in the above step. Upon addition of the aqueous solution, as shown in FIG. 3B, a positive charge of, for example, nitrogen atoms in the organic ammonium ions 5 and a negative charge of the layers 3 constituting the clay mineral attract each other, thereby causing intrusion of the organic ammonium ions 5 between each layer 3 of the clay mineral having the layered structure (montmorillonite) 6 to form a organized clay 4.

Then, a precipitate of the organized clay 4 was recovered by filtration, washed with water and freeze-dried to form a organized clay (organized montmorillonite) 4. The organized clay was named sample e1.

Next, the distance between the layers (layer-to-layer length) in the layered structure of the sample e1 was measured with an X-ray diffraction method and a transmission electron microscope (TEM). The results are shown in the following Table 1.

Next, 7 parts by weight of the organized clay (sample e1) and 85 parts by weight of hexahydroacid anhydride as a curing agent were mixed in a bead mill. Then, the resulting mixture was added to 100 parts by weight of bisphenol A-type epoxy resin, and the mixture was mixed, by stirring for about 30 minutes at a temperature of about 60° C., under the vacuum defoaming conditions (pressure of 3 to 5 torr). Through this process, the epoxy resin was intruded into between the layers of the organized clay, thereby producing the separated layers of the organized clay. As a result, each layer of the organized clay (nano-filling material 3) was dispersed in the epoxy resin 2 to produce an insulating material 1 (see, FIG. 2). The product was named sample E1.

Thereafter, the sample El was heated and cured to obtain a cured sample E1. For the resulting cured sample E1, a thickness and width of the nano-filling material were measured with an X-ray diffraction method and a transmission electron microscope (TEM). As a result of this measurement, it was found in the sample E1 that the layers constituting the clay mineral are separated into a substantially single layer, respectively, and thus the plate-shaped nano-filling materials having widths 100 nm×100 nm and a thickness of about 1 nm were dispersed in the epoxy resin. Further, the containing ratio of the nano-filling materials in the sample E1 is similar to the mixing ratio of the organized clay, and is 7 parts by weight based on 100 parts by weight of the epoxy resin.

In addition, in this example, three types of the organized clays (sample e2, sample e3 and sample c1) were prepared using organic ammonium ions which are different from the organic ammonium ions used in the preparation of the sample e1. Using the resulting organized clays, three types of the insulating materials (sample E2, sample E3 and sample C1) were prepared in accordance with the manner similar to that used in the preparation of sample E1.

More particularly, for the preparation of the sample e2, a organic ammonium salt was first dissolved in water to prepare an aqueous solution of the organic ammonium. The resulting aqueous solution of the organic ammonium contains organic ammonium ions represented by the following formula (5).

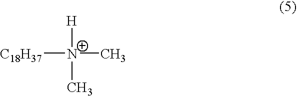

Next, as in the preparation of the sample e1, the aqueous solution of the organic ammonium was added to a dispersion of the clay mineral (montmorillonite). A precipitate of the organized clay was recovered by filtration, washed and freeze-dried to form a organized clay (sample e2).

Further, for the preparation of the sample e3, a organic ammonium salt was dissolved in water to prepare an aqueous solution of the organic ammonium. The resulting aqueous solution of the organic ammonium contains organic ammonium ions represented by the following formula (6).

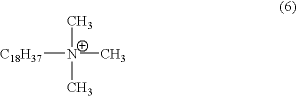

Next, as in the preparation of the sample e1, the aqueous solution of the organic ammonium was added to a dispersion of the clay mineral (montmorillonite). A precipitate of the organized clay was recovered by filtration, washed and freeze-dried to form an organized clay (sample e3).

Furthermore, for the preparation of the sample c1, a organic ammonium salt was dissolved in water to prepare an aqueous solution of the organic ammonium. The resulting aqueous solution of the organic ammonium contains organic ammonium ions represented by the following formula (7).

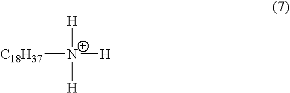

Next, as in the preparation of the sample e1, the aqueous solution of the organic ammonium was added to a dispersion of the clay mineral (montmorillonite). A precipitate of the organized clay was recovered by filtration, washed and freeze-dried to form a organized clay (sample c1).

After preparation of the samples (sample e2, sample e3 and sample c1), each sample was examined as in the manner for the sample e1 to determine the line-to-line length in the layered structure. The results are summarized in the following Table 1.

Next, as in the manner for the sample e1, a organized clay of each sample (sample e2, sample e3 and sample c1), an epoxy resin and a curing agent were mixed to obtain an insulating material in which each layer of the organized clay (nano-filling material) is dispersed in the epoxy resin.

In the resulting insulating materials, the insulating material prepared using the organized clay sample e2 is named as a sample E2, the insulating material prepared using the organized clay sample e3 is named as a sample E3, and the insulating material prepared using the organized clay sample c1 is named as a sample C1. In each of the samples, the nano-filling materials having a thickness of not more than 2 nm and an aspect ratio of not more than 40 are dispersed in the epoxy resin. Further, a containing ratio of the nano-filling material in each of the samples E2, E3 and C1 was similar to that of the sample E1, and was 7 parts by weight per 100 parts by weight of the epoxy resin.

In addition to these samples, for the comparative purpose in this example, an insulating material (sample C2) was prepared without an organized clay.

That is, as in the preparation of the sample E1, 100 parts by weight of a bisphenol A-type epoxy resin as an epoxy resin and 85 parts by weight of hexahydroacid anhydride as a curing agent were mixed, by stirring under the vacuum defoaming conditions, to prepare a comparative insulating material named a sample C2.

Thereafter, a glass transition temperature (Tg) and a withstand voltage were measured for 5 types of the samples (samples E1 to E3 and samples C1 and C2) prepared in the above processes. The results are summarized in the following Table 2.

The measurement of Tg was carried out by the TMA (thermomechanical analysis) method. To measure Tg. each sample was heated at the temperature of 90° C. for 17 hours, followed by further heating at 170° C. for 15 hours to produce a cured product. A temperature of the cured product was increased at an elevation rate of 2.0° C./min. in the thermomechanical tester TM-1500 type (made of Ulvac-Riko Inc.).

The withstand voltage was measured in the dielectric breakdown testing machine (made of Yamayo Tester Co.Ltd.).

More particularly, as is shown in FIG. 3, the insulating materials, i.e., the above-described heated and cured samples, were each molded to obtain a test piece 1 having a cubic configuration. Next, a conductive paste was applied and baked onto one surface of the cubic test piece 1 to form an electrode surface 10. Then, a needle electrode 8 (φ30 μm) was inserted into the test piece 1 from its surface opposed to the electrode surface 10. An electric voltage wad applied to between the needle electrode 8 and the electrode surface 10 to measure the time (breakdown time) necessary to cause a dielectric breakdown. Note the distance between the needle electrode 8 and the electrode surface 10 was 2 mm.

Next, the voltage (dielectric breakdown) at which the breakdown time amounts to 1,000 hours was calculated from the relation of the breakdown time and the applied voltage. The results are summarized in the following Table 2.

TABLE 1

| | | | | Layer- |
|---|---|---|---|---|
| | | | | to- |
| | | | | layer |
| No. of | Type of clay | | | length |
| sample | mineral | Organic ammonium ions | | (nm) |
| Sample | Montmorillonite | Secondary | N-methyl n- | 3.9 |
| e1 | | | octadecyl | |
| | | | ammonium ion | |
| Sample | Montmorillonite | Tertiary | N,N-dimethyl n- | 3.7 |
| e2 | | | octadecyl | |
| | | | ammonium ion | |
| Sample | Montmorillonite | Quaternary | Trimethylstearyl | 3.4 |
| e3 | | | ammonium ion | |
| Sample | Montmorillonite | Primary | Stearyl ammonium | 5.7 |
| c1 | | | ion | |

TABLE 2

| | | | Epoxy | | | |
|---|---|---|---|---|---|---|
| | | | resin | Curing | | |
| | | | (bisphenol | agent | | Dielec- |
| | Organized | | A-type | (hexahydro | | tric |
| | clay | | epoxy | acid | | break- |
| No. of | | Amount | resin) | anhydride) | Tg | down |
| sample | type | (pbw) | (pbw) | (pbw) | (° C.) | (kV/mm) |
| E1 | E1 | 7 | 100 | 85 | 135 | 150 |
| E2 | E2 | 7 | 100 | 85 | 135 | 152 |
| E3 | E3 | 7 | 100 | 85 | 135 | 151 |
| C1 | C1 | 7 | 100 | 85 | <40 | 0 |
| C2 | — | 0 | 100 | 85 | 135 | 50 |

pbw: parts by weight

As can be appreciated from Table 1, all of the organized clays prepared using the organic primary to quaternary ammonium ions (samples e1 to e3 and sample c1) showed an increased layer-to-layer length in comparison with that of the unorganized clay mineral (montmorillonite). Note that the unorganized clay mineral (montmorillonite) had a layer-to-layer length of about 1 nm.

Further, as can be appreciated from Table 2, of the insulating materials prepared using the organized clays, samples e1 to e3 (samples E1 to E3) showed a high dielectric breakdown of at least 150 kV/mm. These dielectric breakdowns are at least three times that of the sample C2 having no clay.

Contrary to this, in the insulating material (sample C1) prepared using the organized clay sample c1, it was observed that the dielectric breakage is remarkably reduced in comparison with that of the sample C2.

As can be understood from the above results, the insulating materials (samples E1 to E3) obtained by dispersing, in the epoxy resin, organized clays (samples e1 to e3) prepared by using the organic secondary, tertiary or quaternary ammonium ions can exhibit an excellent insulating property, whereas the insulating material (sample C1) obtained by dispersing, in the epoxy resin, organized clays (sample c1) prepared by conducting an organization treatment using the organic primary ammonium ions cannot exhibit an insulating property.

The reason is considered to be because, in the insulating material (sample C1) containing the organic primary ammonium ions, when this insulating material is cured upon heating, the organic primary ammonium ions can adversely effect on the curing reaction of the epoxy resin.

Moreover, the samples E1 to E3 can exhibit the above-described excellent insulating properties, when they contain a small amount of the nano-filling material such as about 7 parts by weight per 100 parts by weight of the epoxy resin. Due to this, the samples E1 to E3 can exhibit the insulating properties without causing a substantial deterioration of the characteristics inherent to the epoxy resin.

More particularly, as can be appreciated from Table 2, the samples E1 to E3 showed a glass transition temperature which is substantially the same as that of the sample C2 consisting of the epoxy resin. On the other hand, the sample C1 showed a glass transition temperature which is lower than that of the sample C2.

That is, the samples E1 to E3 can exhibit an excellent glass transition temperature which is equivalent to that of the sample C2 containing no nano-filling material.

As is described above, the insulating material samples E1 to E3 in this example can exhibit an excellent insulating property without suffering from a substantial loss of the characteristics of the resin itself.

1. An insulating material comprising an epoxy resin, a curing agent and a nano-filling material having an aspect ratio of not more than 40 at a thickness of not more than 2 nm, wherein
the nano-filling material comprises an organized clay dispersed in the expoxy resin, and
the organized clay comprises a clay mineral having a layered structure organically treated with organic secondary, tertiary or quaternary ammonium ions having a nitrogen atom bonded with two, three or four organic modifying groups.

2. The insulating material as defined in claim 1, wherein the organic modifying groups bonded to the organic ammonium ions have not more than 30 carbon atoms.

3. The insulating material as defined in claim 1, wherein at least one of the organic modifying groups bonded to the organic ammonium ions has two or more carbon atoms.

4. The insulating material as defined in claim 1, wherein at least one of the organic modifying groups bonded to the organic ammonium ions has two or more carbon atoms, and the remainder of the organic modifying groups has 30 or fewer carbon atoms.

5. The insulating material as defined in claim 1, wherein the clay mineral is at least one member selected from montmorillonite, sabonite, beidellite, nontronite, hectorite and stevensite.

6. The insulating material as defined in claim 5, wherein the organic modifying groups bonded to the organic ammonium ions have not more than 30 carbon atoms.

7. The insulating material as defined in claim 5, wherein at least one of the organic modifying groups bonded to the organic ammonium ions has two or more carbon atoms.

8. The insulating material as defined in claim 1, wherein at least one of the organic modifying groups bonded to the organic ammonium ions has two or more carbon atoms, and the remainder of the organic modifying groups has 30 or fewer carbon atoms.

9. The insulating material as defined in claim 1, wherein the insulating mineral contains 1 to 35 parts by weight of the nano-filling material per 100 parts by weight of the epoxy resin.

10. The insulating material as defined in claim 9, wherein the organic modifying groups bonded to the organic ammonium ions have not more than 30 carbon atoms.

11. The insulating material as defined in claim 9, wherein at least one of the organic modifying groups bonded to the organic ammonium ions has two or more carbon atoms.

12. The insulating material as defined in claim 9, wherein at least one of the organic modifying groups bonded to the organic ammonium ions has two or more carbon atoms, and the remainder of the organic modifying groups has 30 or fewer carbon atoms.
